(19) United States
(12) Patent Application Publication
(10) Pub. No.: US 2009/0238956 A1
(43) Pub. Date: Sep. 24, 2009

(54) MANUFACTURING METHOD OF A WIRING BOARD CONTAINING A SEED LAYER HAVING A ROUGHENED SURFACE

(75) Inventor: Hironari KOJIMA, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/406,161

(22) Filed: Mar. 18, 2009

(30) Foreign Application Priority Data
Mar. 19, 2008 (JP) 2008-071583
Sep. 1, 2008 (JP) 2008-223635

(51) Int. Cl. H05K 3/00

(52) U.S. Cl. 427/98.5

(57) ABSTRACT

A seed layer is formed on a top surface of an insulating layer so that a top surface of the seed layer has a predetermined roughness. A resist film is formed on the top surface of the seed layer, the resist film having an opening part through which a portion of the top surface of the seed layer corresponding to an area where a wire is formed is exposed. The wire is formed on the top surface of the seed layer by an electrolytic plating method using the seed layer as an electric supply layer. The resist film is removed after forming the wire. A portion of the seed layer on which the wire is not formed is removed.

### CROSS-REFERENCE TO RELATED APPLICATIONS

This application is based upon and claims the benefit of priority of the prior Japanese Patent Applications No. 2008-071583 filed on Mar. 19, 2008 and No. 2008-223635 filed on Sep. 1, 2008, the entire contents of which are incorporated herein by reference.

### FIELD

The present invention relates to a wiring board and, more particularly, to a manufacturing method of a wiring board having a seed layer on which a wire is formed.

### BACKGROUND

FIG. 1 is a cross-sectional view of a wiring board.

The wiring board 100 illustrated in FIG. 1 includes an insulating layer 101, a seed layer 102, and wires 103. A top surface 101A of the insulating layer 101 is processed to be a roughened surface. Thereby, a minute concavity and convexity is formed on the top surface 101A of the insulating layer 101. Such a minute concavity and convexity is provided for forming a minute concavity and convexity on a top surface 102A of the seed layer 102, more specifically, for transferring the minute concavity and convexity onto the top surface 102A of the seed layer 102 formed on the top surface 101A of the insulating layer 101. An arithmetic mean roughness Ra of the top surface 101A of the insulating layer 101 can be set to, for example, 0.5 μm or larger. For example, a resin layer can be used as the insulating layer 101.

The seed layer 102 is formed on the upper surface 101A of the insulating layer 101 in a portion corresponding to a formation area of each wire 103. A lower portion of the seed layer 102 is formed so that the lower portion enters into the minute concave portion formed on the upper surface 101A of the insulating layer 101. A minute concavity and convexity is formed on the top surface 102A of the seed layer 102. The seed layer 102 is used as an electricity supply layer when forming the wires 103 by an electrolytic plating method. For example, a Cu layer can be used as the seed layer 102. When a Cu layer is used as the seed layer 102, a thickness of the seed layer 102 can be set to 1 μm.

The wires 103 are formed on the seed layer 102. The wires 103 are formed on the top surface 102A of the seed layer 102 by depositing a Cu plating film on the top surface 102 of the seed layer 102 by an electroplating method using the seed layer 102 as an electric supply layer.

A description will be given below of the manufacturing method of the wiring board 100. FIG. 2 through FIG. 8 illustrate a manufacturing process of the wiring board 100. In FIG. 2 through FIG. 8, parts that are the same as the parts illustrated in FIG. 1 are given the same reference numerals.

First, the insulating layer 101 is formed in the process illustrated in FIG. 2. It this stage, the surface 101A of the insulating layer 101 is a smooth surface.

Subsequently, in the process illustrated in FIG. 3, a roughening process is applied to the top surface 101A of the insulating layer 101 illustrated in FIG. 2. In the roughening process, the top surface 101A of the insulating layer 101 is processed so that an arithmetic mean roughness Ra of the top surface 101 becomes about 0.5 μm. Thereby, minute concavity and convexity is formed on the top surface 101A of the insulating layer 101.

Subsequently, in the process illustrated in FIG. 4, the seed layer 102 is formed to cover the top surface 101A of the insulating layer 101 illustrated in FIG. 3. The minute concavity and convexity formed on the top surface 101A of the insulating layer 101 is transferred to the seed layer 102, thereby forming minute concavity and convexity on the top surface 102A of the seed layer 102. A lower part of the seed layer 102 is formed to enter the minute concavity formed on the top surface 101A of the insulating layer 101. A Cu layer, for example, may be used as the seed layer 102.

Subsequently, in the process illustrated in FIG. 5, a resist film 105, which is used as a mask in a plating process, is formed on the top surface 102A of the seed layer 102. The resist film 105 has an opening part 105A, through which a portion of the top surface 102A of the seed layer 102 corresponding to a formation area of each wire 103, is exposed.

Thus, the adhesion between the seed layer 102 and the resist film 105 can be improved by providing the minute concavity and convexity on the top surface 102A of the seed layer 102.

Subsequently, in the process illustrated in FIG. 6, the wires 103 are formed on the top surface 102A of the seed layer 102 on which the minute concavity and convexity is formed, by depositing a Cu plating film on the top surface 102A of the seed layer 102 by an electroplating method using the seed layer 102 as an electric supply layer. In this process, because a lower portion of the resist film 105 protrudes into the minute concavity formed on the top surface 102A of the seed layer 102, the resist film 105 firmly engages the seed layer 102. Thus, the resist film 105 is prevented from being separated from the seed layer 102, which separation is caused by a plating solution entering between the seed layer 102 and the resist film 105.

Subsequently, in the process illustrated in FIG. 7, the resist film 105 illustrated in FIG. 6 is removed. Subsequently, as illustrated in FIG. 8, a portion of the seed layer 102, which portion is not covered by the wires 103, is removed by immersing the material body illustrated in FIG. 7 including the seed layer 102 into an etching solution for etching Cu. Thus, the wiring board 100 is completed. For example, the above-mentioned manufacturing method is suggested in Patent Document 1.

Patent Document 1: Japanese Laid-Open Patent Application No. 11-214828

As mentioned above, the seed layer 102 is formed on the top surface 101A of the insulating layer 101 on which the minute concavity and convexity is formed in the wiring board 100. Accordingly, a considerable time (etching time) must be spent on removing the unnecessary portion of the seed layer 102 by etching in the process of FIG. 8.

Thus, there is a problem in that the wires 103 are etched by the etching solution for removing the unnecessary portion of the seed layer 102, which results in reducing the size of each wire 103 (specifically, the designed width and thickness of each wire 103) after the removal of the unnecessary portion of the seed layer 102. This problem may be critical particularly in a case where the width and thickness of each wire 103 is small (for example, the width of the wire is equal to or smaller than 10 μm).

### SUMMARY

It is a general object of the present invention to provide a manufacturing method of a wiring board in which the above-mentioned problems are eliminated.

A more specific object of the present invention is to prevent a resist film, which is used as a mask in plating, from being separated from a seed layer.

According to an aspect of the present invention, there is provided a manufacturing method of a wiring board, comprising: forming a seed layer on a top surface of an insulating layer so that a top surface of the seed layer has a predetermined roughness; forming a resist film on the top surface of the seed layer, the resist film having an opening part through which a portion of the top surface of the seed layer corresponding to an area where a wire is formed is exposed; forming the wire on the top surface of the seed layer by an electrolytic plating method using the seed layer as an electric supply layer; removing the resist film after forming the wire; and removing a portion of the seed layer on which the wire is not formed.

According to the present invention, the resist film, which is used as a mask in plating, is prevented from being separated from the seed layer. Additionally, an etching time spent on removing an unnecessary portion of the seed layer is reduced, which results in prevention of a reduction in a size of a wire after a process of removing a seed layer.

Other objects, features and advantages of the present invention will become more apparent from the detailed description when read in conjunction with the accompanying drawings.

It is to be understood that both the foregoing general description and the following detailed description are exemplary explanatory only and are not restrictive of the invention, as claimed.

### BRIEF DESCRIPTION OF DRAWINGS

FIG. 1 is a cross-sectional view of a part of a wiring board;

FIG. 2 is a cross-sectional view for explaining a first process of manufacturing the wiring board illustrated in FIG. 1;

FIG. 3 is a cross-sectional view for explaining a second process of manufacturing the wiring board illustrated in FIG. 1;

FIG. 4 is a cross-sectional view for explaining a third process of manufacturing the wiring board illustrated in FIG. 1;

FIG. 5 is a cross-sectional view for explaining a fourth process of manufacturing the wiring board illustrated in FIG. 1;

FIG. 6 is a cross-sectional view for explaining a fifth process of manufacturing the wiring board illustrated in FIG. 1;

FIG. 7 is a cross-sectional view for explaining a sixth process of manufacturing the wiring board illustrated in FIG. 1;

FIG. 8 is a cross-sectional view for explaining a seventh process of manufacturing the wiring board illustrated in FIG. 1;

FIG. 9 is a cross-sectional view of a part of a wiring board according to an embodiment of the present invention;

FIG. 10 is a cross-sectional view for explaining a first process of manufacturing the wiring board according to the embodiment of the present invention;

FIG. 11 is a cross-sectional view for explaining a second process of manufacturing the wiring board according to the embodiment of the present invention;

FIG. 12 is a cross-sectional view for explaining a third process of manufacturing the wiring board according to the embodiment of the present invention;

FIG. 13 is a cross-sectional view for explaining a fourth process of manufacturing the wiring board according to the embodiment of the present invention;

FIG. 14 is a cross-sectional view for explaining a fifth process of manufacturing the wiring board according to the embodiment of the present invention;

FIG. 15 is a cross-sectional view for explaining a sixth process of manufacturing the wiring board according to the embodiment of the present invention;

FIG. 16 is a cross-sectional view for explaining a seventh process of manufacturing the wiring board according to the embodiment of the present invention; and

FIG. 17 is an illustration indicating a reduction in a film thickness by etching.

### DESCRIPTION OF EMBODIMENT(S)

Preferred embodiment of the present invention will be explained with reference to the accompanying drawings.

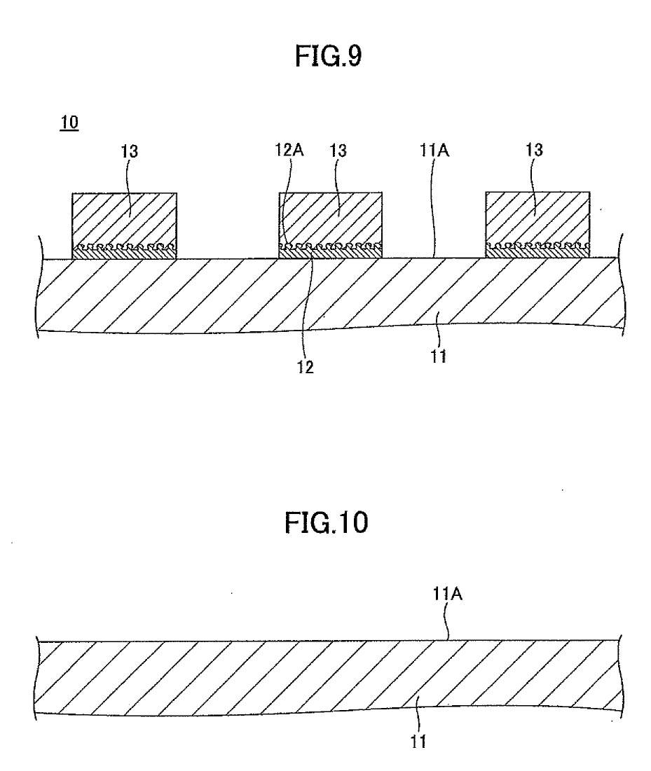

FIG. 9 is a cross-sectional view of a wiring board according to an embodiment of the present invention.

With reference to FIG. 9, the wiring board 10 according to the present embodiment comprises an insulating layer 11, a seed layer 12 and wires 13. The wiring board 10 can be, for example, a coreless board, a buildup board or the like. FIG. 9 illustrates a part of the wiring board 10.

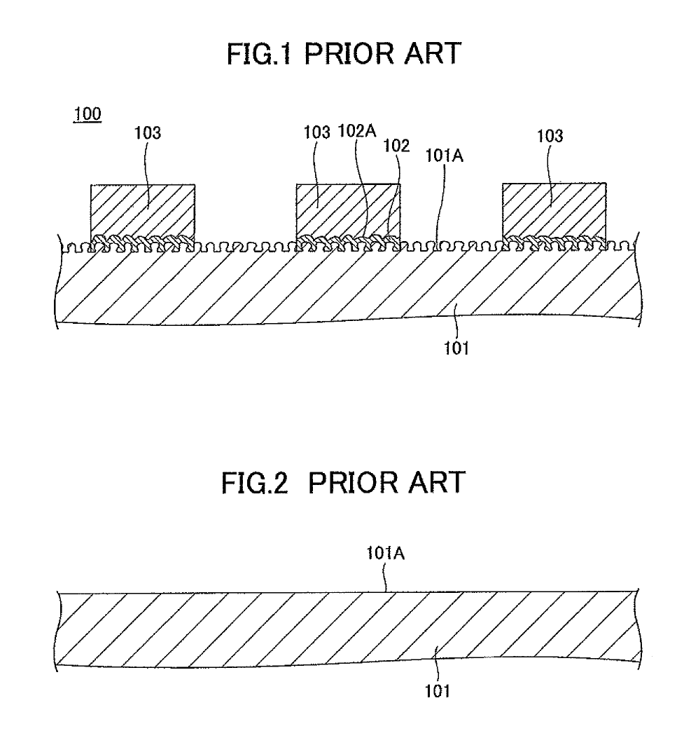

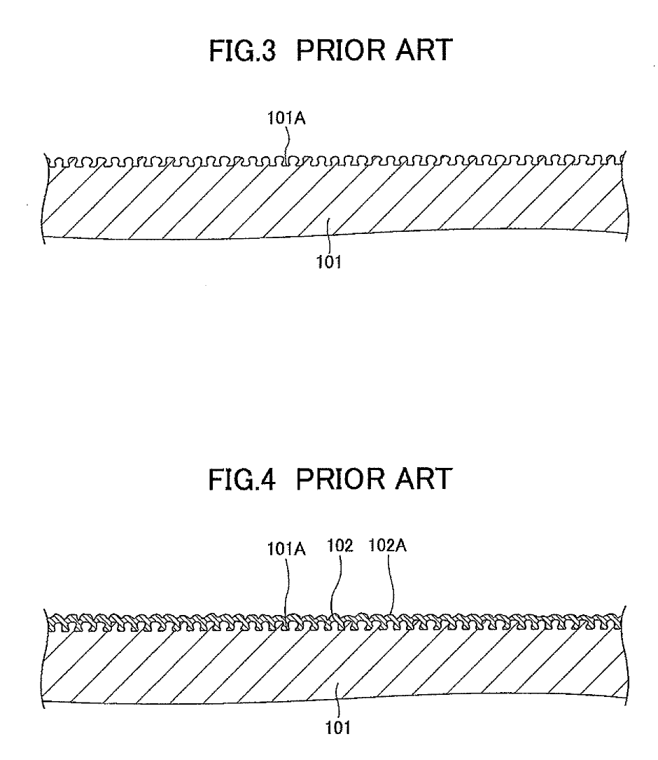

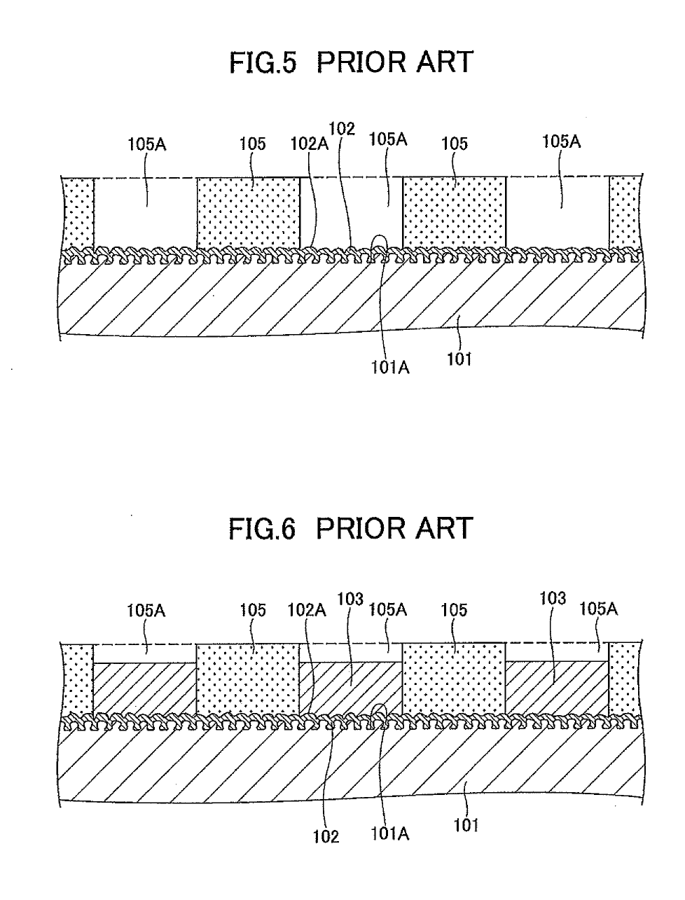

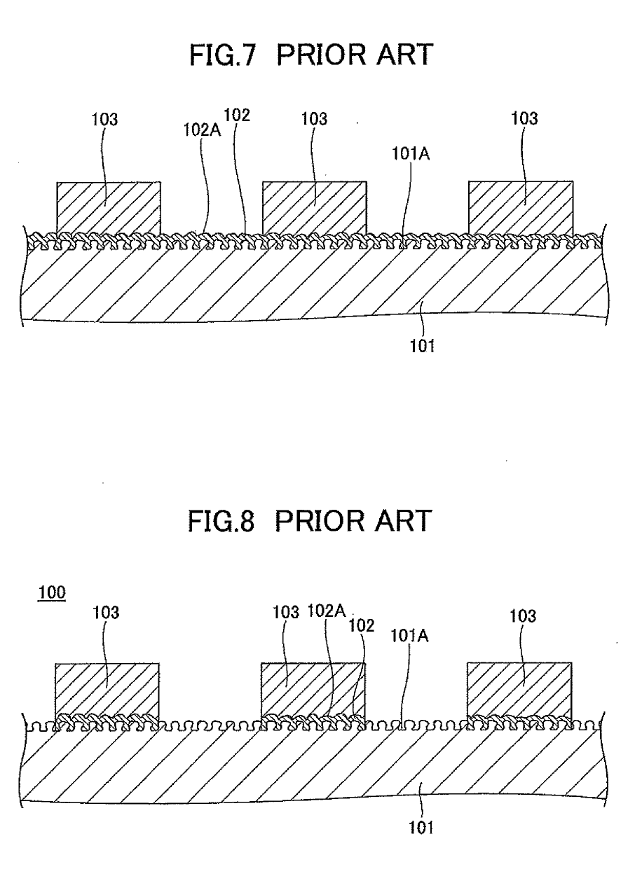

The insulating layer 11 is provided for forming the seed layer 12 thereon. A top surface 11A of the insulating layer 11 is made into a surface smoother than the top surface 101A of the insulating layer 101 illustrated in FIG. 1. For example, the top surface 11A has an arithmetic mean roughness Ra equal to or smaller that 0.4 μm (Ra≦0.4 μm).

By making the top surface 11A of the insulating layer 11 into such a smooth surface, when removing an unnecessary portion of the seed layer 12 (refer to the process illustrated in FIG. 16 mentioned later), the unnecessary portion of the seed layer 12 can be removed within a short period of time, which permits each wire 13 to be formed in an exact size as desired after being subjected to a seed layer removing process.

For example, a resin layer can be used as the insulating layer 11. An epoxy resin or a polyimide resin can be used as the material of the resin layer.

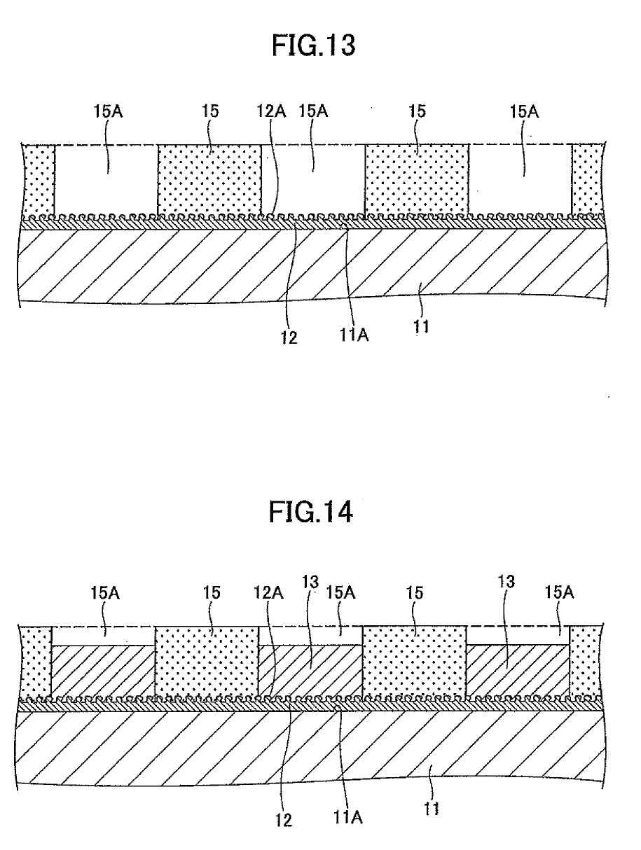

The seed layer 12 is provided in a portion corresponding to a formation area of the wires 13 on the top surface of the insulating layer 11. The seed layer 12 is an electric supply layer used when forming the wires 13 by an electrolytic plating method. A resist film 15 (refer to FIG. 13 mentioned later) for forming the wires 13 is formed on a top surface 12A of the seed layer 12. The top surface 12A of the seed layer 12 is a roughened surface on which minute concavity and convexity is formed. An arithmetic mean roughness Ra of the top surface 12A of the seed layer 12 can be set, for example, to be equal to or larger than 0.10 μm (Ra≧0.10 μm).

Thus, by setting the arithmetic mean roughness Ra of the top surface 12A of the seed layer 12 to be equal to or larger than 0.10 μm (Ra≧0.10 μm), the resist film 15 used in a plating process for forming the wires 13 can be prevented from being separated from the seed layer 12. If the arithmetic mean roughness Ra of the top surface 12A of the seed layer 12 is smaller than 0.10 μm (Ra<0.10 μm), the resist film 15 for forming the wires 13 may be separated from the seed layer 12.

Additionally, by setting the arithmetic mean roughness Ra of the top surface 12A of the seed layer 12 to be equal to or larger than 0.10 μm (Ra≧0.10 μm), the surface area of the seed layer 12 is increased as compared to the seed layer 102 of the wiring board 100 illustrated in FIG. 1. Thus, an area of the surface of the seed layer 12, which area is brought into contact with an etching solution when etching and removing an unnecessary portion of the seed layer 12, is larger than that of the seed layer 102 of the wiring board 100. As a result, if the seed layer 12 and the seed layer 102 have the same mass, a time spent on etching the seed layer 12 can be shorter than a time spent on etching the seed layer 102. Thereby, unnecessary etching of parts (the wires 13) other than the seed layer 12 can be suppressed. Because the unnecessary etching of the wires 13 is suppressed, it is particularly effective in forming wires 13 having a small width (specifically, the wires 13 having a width of 10 μm or smaller).

More preferably, the arithmetic mean roughness Ra of the top surface 12A of the seed layer 12 is set to be equal to or larger than 0.1 μm and equal to or smaller than 0.5 μm (0.10 μm≦Ra≦0.5 μm).

By setting the arithmetic mean roughness Ra of the top surface 12A of the seed layer 12 to be equal to or larger than 0.1 μm and equal to or smaller than 0.5 μm (0.10 μm≦Ra≦0.5 μm), it becomes possible to form the wires 13 having a small width (for example, the wires 13 having a width equal to or smaller than 10 μm) with high accuracy. If the arithmetic mean roughness Ra of the top surface 12A of the seed layer 12 is larger than 0.5 μm (Ra>0.5 μm), it is difficult to form the wires 13 having a small width (for example, the wires 13 having a width equal to or smaller than 10 μm) with good accuracy.

For example, a Cu layer can be used as the seed layer 12. If a Cu layer is used as the seed layer 12, the thickness of the seed layer 12 having a roughened top surface 12A can be, for example, 1 μm.

The wires 13 are provided on the roughened top surface 12A of the roughened seed layer 12. For example, Cu can be used as the material of the wires 13.

FIG. 10 through FIG. 16 are cross-sectional views illustrating a manufacturing process of the wiring board 10 according to the present embodiment. In FIGS. 10 through FIG. 16, parts that are the same as the parts illustrated in FIG. 9 are given the same reference numerals.

A description will be given below, with reference to FIG. 10 through FIG. 16, of the manufacture method of the wiring board 10 according to the present embodiment. First, in the process illustrated in FIG. 10, the insulating layer 11 having a smoothed top surface 11A is formed. For example, a resin layer can be used as the insulating layer 11. An epoxy resin or a polyimide resin can be used as the resin layer. Specifically, if a resin layer is used as the insulating layer 11, for example, a half-cured resin film is laminated, and, thereafter, the resin film is completely cured to form the resin layer. The top surface 11A of the insulating layer 11 is a smoother surface than the roughened top surface 101A of the insulating layer 101 illustrated in FIG. 1. For example, the arithmetic mean roughness Ra of the top surface 11A of the insulating layer 11 is set to be equal to or smaller than 0.4 μm (Ra≧0.4 μm).

Thus, by making the top surface 11A of the insulating layer 11 into a smooth surface, the seed layer 12 can be remove by etching within a shorter time than a conventional method, when removing an unnecessary portion of the seed layer 12 using an etching solution in the process (seed layer removing process) illustrated in FIG. 16, as described later. Thereby, the wires 13 are hardly etched in the process (seed layer removing process) illustrated in FIG. 16 mentioned later, which permits formation of each wire 13 having a predetermined size (specifically, the wire 13 having a predetermined width and thickness). The predetermined width of the wire 13 means a designed width of the wire 13, and the predetermined thickness of the wire 13 means a designed thickness of the wire 13.

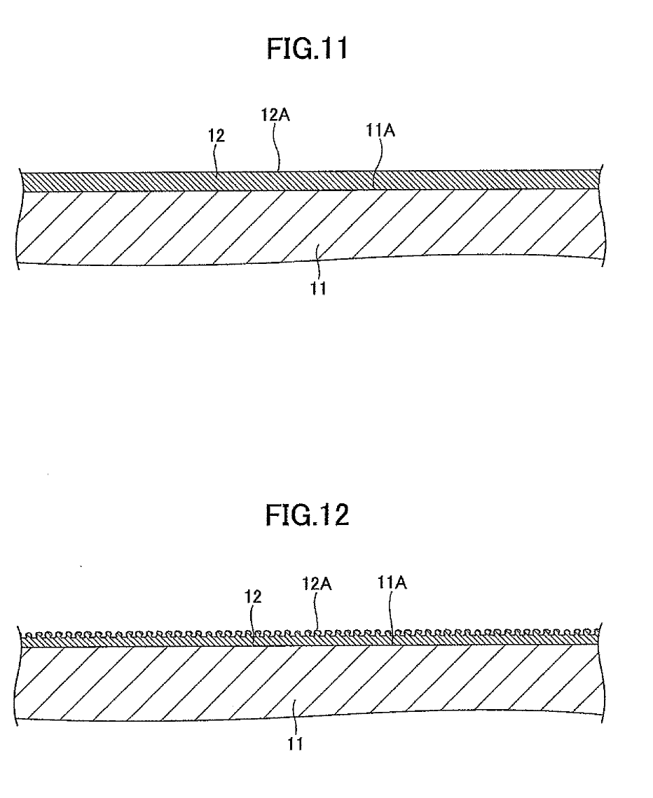

Subsequently, in the process illustrated in FIG. 11, the seed layer 12 is formed to cover the smoothed top surface 11A of the insulating layer 11 (seed layer forming process). Specifically, the seed layer 12 is formed by an electroless plating method, a sputtering method, a vapor deposition method, or the like. At this stage, the top surface 12A of the seed layer 12 is a smooth surface. For example, a Cu layer can be used as the seed layer 12.

The thickness of the seed layer 12 at this stage is preferably set to be larger than the thickness of the seed layer 12 illustrated in FIG. 9 mentioned before in consideration of the reduction in the thickness of the seed layer 12 in the process (seed layer roughening process) illustrated in FIG. 12.

Specifically, a Cu layer is used as the seed layer 12 and if the thickness of the seed layer 12 illustrated in FIG. 9 is 1 μm, the thickness of the seed layer 12 in the seed layer forming process may be set to, for example, 2 μm to 3 μm.

Subsequently, in the process illustrated in FIG. 12, the top surface 12A of the seed layer 12 illustrated in FIG. 11 is roughened (seed layer roughening process). Specifically, roughening of the seed layer 12 is performed by applying a blasting process on the top surface 12A of the seed layer 12 or etching the top surface 12A of the seed layer 12 (for example, etching by spraying an atomized etching solution). Thereby, minute concavity and convexity is formed on the top surface 12A of the seed layer 12. In a case where a roughening process is carried out by spraying an etching solution, CZ-8101 (manufactured by MEC Company Limited) may be used as an etching solution. CZ-8101 (manufactured by MEC Company Limited) is an etching solution containing formate by equal to or less than 10%. When using CZ-8101 (manufactured by MEC Company Limited) as an etching solution, a pressure to spray the etching solution from a spray machine is, for example, 0.2 MPa. In this process, a process temperature may be set to, for example, 30° C., and a process time may be set to, for example, 30 seconds to 60 seconds.

In the seed layer roughening process, the roughening process is performed so that the arithmetic mean roughness Ra of the top surface 12A of the seed layer 12 is set to be equal to or larger than 0.10 μm (Ra≧0.10 μm).

Thus, the resist film 15 (refer to FIG. 13 mentioned later) formed on the top surface 12A of the seed layer 12 can be prevented from being separated from the seed layer 12 because the adhesion between the resist film 15 and the seed layer 12 is improved by the arithmetic mean roughness Ra of the top surface 12A of the seed layer 12 being set equal to or larger than 0.10 μm (Ra≧0.10 μm). If the arithmetic mean roughness Ra of the top surface 12A of the seed layer 12 is smaller than 0.10 μm (Ra<0.10 μm), the adhesion between the resist film 15 and the seed layer 12 is insufficient, which may result in separation of the seed layer from the seed layer 12.

Preferably, the arithmetic mean roughness Ra of the top surface 12A of the seed layer 12 may be set to be, for example, equal to or larger than 0.10 μm and equal to or smaller than 0.5 μm (0.10 μm≦Ra≦0.5 μm).

Thus, the wires 13 having a small width (for example, the wires 13 having a width equal to or smaller than 10 μm) can be formed with high accuracy by setting the arithmetic mean roughness Ra of the top surface 12A of the seed layer 12 to be equal to or larger than 0.10 μm and equal to or smaller than 0.5 μm (0.10 μm≦Ra≦0.5 μm). If the arithmetic mean roughness Ra of the top surface 12A of the seed layer 12 is larger than 0.5 μm (Ra>0.5 μm), it is difficult to form the wires 13 having a small width (for example, the wires 13 having a width equal to or smaller than 10 μm) with high accuracy.

For example, a Cu layer may be used as the seed layer 12. If a Cu layer is used as the seed layer, the thickness of the seed layer 12 after the roughening process can be set to, for example, 1 μm.

Instead of the above-mentioned etching process, a blasting process (for example, a sand-blasting process) may be used to roughen the top surface 12A of the seed layer 12 so that the arithmetic mean roughness Ra of the top surface 12A of the seed layer 12 is set to be equal to or larger than 0.10 μm (Ra≧0.1 μm). In such a case, the same effect as that of the case where the top surface 12A of the seed layer 12 is roughened by etching can be obtained.

Subsequently, in the process illustrated in FIG. 13, the resist film 15 having opening parts 15A is formed on the roughened top surface 12A of the seed layer 12 (resist film forming process). In this process, a lower portion of the resist film 15 enters the minute concavity formed on the top surface of the seed layer 12. The opening parts 15A are provided to expose portions of the top surface 12A of the seed layer 12 which portions correspond to the formation areas of the wires 13.

Thus, the resist film 15 is prevented from being separated from the seed layer because the adhesion between the resist film 15 and the seed layer 12 is improved by the resist film 15 being formed on the roughened top surface 12A of the seed layer 12.

Subsequently, in the process illustrated in FIG. 14, the wires 13 of which base material is a film made by plating are formed on the top surface 12A of the seed layer 12 by using an electrolytic plating method using the seed layer 12 as an electric supply layer. In this process, a plating solution for forming the wires 13 is suppressed from entering the interface between the seed layer 12 and the resist film 15 because the lower portion of the resist film 15 is formed to fit to the minute concavity and convexity of the top surface 12A of the seed layer 12. Thereby the resist film 15 is prevented from being separated from the seed layer 12. For example, a Cu plated film may be used as the plated film, which is a base material of the wires 13.

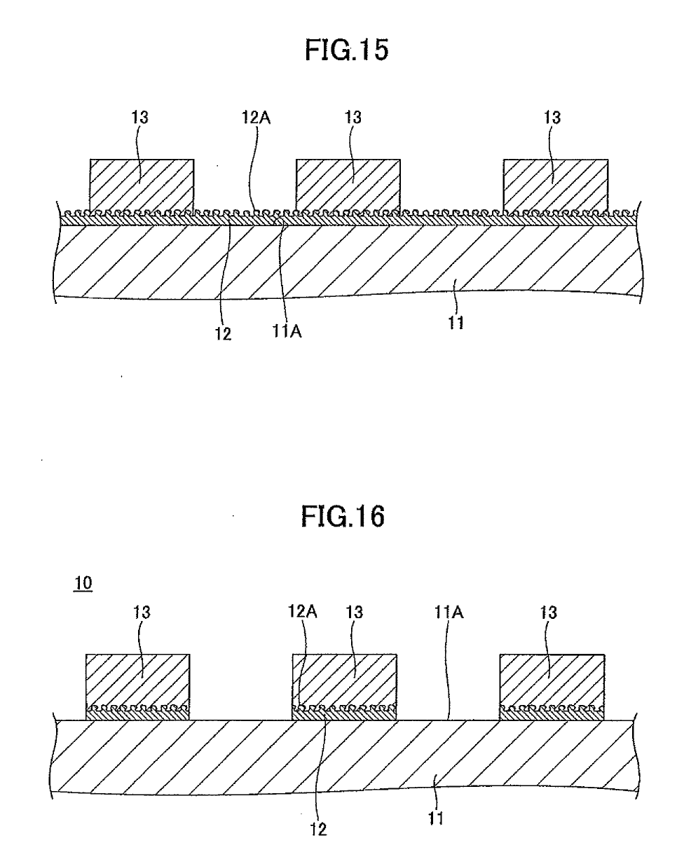

Subsequently, in the process illustrated in FIG. 15, the resist film 15 provided in the structure illustrated in FIG. 14 is removed (resist film removing process). Then, in the process illustrated in FIG. 16, the seed layer 12 (specifically, unnecessary portions of the seed layer 12), which is not covered by the wires 13, is removed (seed layer removing process). Specifically, for example, the unnecessary portions of the seed layer 12 are removed by wet-etching using an etching solution. As the etching solution used in the seed layer removing process, an etching solution of sulfuric acid/hydrogen peroxide base may be used.

The wiring board 10 according to the present embodiment is manufactured by the above-mentioned process. Accordingly, as mentioned before, the unnecessary portions of the seed layer 12 can be removed within a shorter etching time than that of the conventional method because the seed layer 12 is formed on the smoothed top surface 11A of the insulating layer 11. Thus, the wires 13 can be formed so that the size of each wire 13 after the seed layer removing process is exactly a predetermined size as desired. Specifically, each wire 13 after the seed layer removing process has a designed thickness and a designed width.

Moreover, as mentioned above, because the surface area of the seed layer 12 is large as compared with the seed layer 102 of the wiring board 100 illustrated in FIG. 1, an area reacting with the etching solution is increased, which increases an amount of seed layer 12 reacting with the etching solution. As a result, if the seed layer 102 illustrated in FIG. 1 and the seed layer 12 according to the present embodiment have the same mass, the etching time of the seed layer 12 can be shorter than the etching time of the seed layer 102, thereby suppressing unnecessary etching of portions (such as the wires 13) other than the seed layer 12. Because unnecessary etching of the wires 13 is suppressed, the process according to the present embodiment is particularly effective for forming the wires 13 having a small width (specifically, the wire 13 having a width equal to or smaller than 10 μm).

According to the manufacturing method of the wiring board according to the present embodiment, first the seed layer 12 is formed on the insulating layer 11 to cover the smoothed top surface 11A of the insulating layer 11; then, the top surface 12A of the seed layer 12 is roughened; and, thereafter, the resist film 15 is formed on the top surface 12A of the seed layer 12, the resist film 15 having the opening part 15A through which the top surface 12A of the seed layer 12 corresponding to the formation area of each wire 13 is exposed. Thereby, the resist film 15 is prevented from being separated from the seed layer 12.

Additionally, after the seed layer roughening process, the resist film 15 is formed on the top surface 12A of the seed layer, the resist film 15 having the opening part 15A through which the top surface 12A of the seed layer 12 corresponding to the formation area of each wire 13 is exposed; then, the wiring layer is formed on the top surface 12A of the seed layer by an electrolytic plating method using the seed layer as an electric supply layer; subsequently, the resist film 15 is removed; and, thereafter, the unnecessary portion of the seed layer 12 where the wire 13 is not formed is removed. Thereby, the unnecessary portion of the seed layer 12 where the wire 13 is not formed can be removed within a shorter time than that of a conventional method. Thus, the wire 13 can be formed so that the size of the wire 13 after the seed layer removing process is exactly a predetermined size as desired. Specifically, the wire 13 after the seed layer removing process has a designed thickness and a designed width.

Moreover, the surface area of the seed layer 12 can be large as compared to the seed layer 102 of the wiring board 100 illustrated in FIG. 1 by setting the arithmetic mean roughness Ra of the top surface 12A of the seed layer 12 to be equal to or larger than 0.10 μm (Ra≧0.10 μm). Thus, an area of the seed layer 12 reacting with the etching solution is larger than that of the seed layer 102 of the wiring board 100 illustrated in FIG. 1, which results in an increase in the amount of the seed layer 12 reacting with the etching solution. As a result, if the seed layer 102 illustrated in FIG. 1 and the seed layer 12 according to the present embodiment have the same mass, the etching time of the seed layer 12 can be shorter than the etching time of the seed layer 102, thereby suppressing unnecessary etching of a portion (such as the wire 13) other than the seed layer 12. Because unnecessary etching of the wire 13 is suppressed, the process according to the present embodiment is particularly effective for forming the wire 13 having a small width (specifically, the wire 13 having a width equal to or smaller than 10 μm).

In addition, instead of performing the seed layer forming process and the seed layer roughening process mentioned above, the seed layer 12 may be formed on the smoothed top surface 11A of the insulating layer 11 by an electroless plating method so that the seed layer 12 has an aciculate (needle-like) surface. For example, the seed layer 12 having an aciculate surface can be formed by an electroless plating layer (Cu—Ni—P alloy layer) made of a Cu—Ni—P alloy containing Cu (90 wt % to 96 wt %), Ni (1 wt % to 5 wt %) and P (0.5 wt % to 2 wt %). By using the Cu—NI—P alloy having the above-mentioned composition as the seed layer 12, minute needle-like concavity and convexity can be formed on the top surface of the seed layer 12 (Cu—Ni—P alloy layer) formed by an electroless plating method.

The arithmetic mean roughness Ra of the top surface 12A of the seed layer 12 (Cu—Ni—P alloy layer) can be set to be equal to or larger than 0.10 μm (Ra≧0.10 μm). Preferably, the arithmetic mean roughness Ra of the top surface 12A of the seed layer 12 (Cu—Nil-P alloy layer) may be set to be equal to or larger than 0.10 μm and equal to or smaller than 0.5 μm (0.10 μm≦Ra≦0.5 μm). According to such an arithmetic mean roughness Ra, an effect the same as that explained before can be obtained.

A description will be given below of a result of investigation performed on the relationship between a presence of the roughening process and an etching rate.

Four samples (sample No. 1 through sample No. 4) indicated in the following Table 1 were prepared. Two pieces of each of the samples No. 1 through No. 4 were prepared to confirm repeatability of the result.

TABLE 1

| | | | ARITHMETIC |
|---|---|---|---|
| | ELECTROLYTIC/ | ROUGHENING | MEAN |
| SAMPLE | ELECTROLESS | PROCESS | ROUGHNESS Ra |
| 1 | ELECTROLESS | NO | 0.07 μm |
| | Cu PLATING | | |
| 2 | ELECTROLESS | YES | 0.31 μm |
| | Cu PLATING | | |
| 3 | ELECTROLYTIC | NO | 0.09 μm |
| | Cu FOIL | | |
| 4 | ELECTROLYTIC | YES | 0.24 μm |
| | Cu FOIL | | |

The sample No. 1 had a layer corresponding to the seed layer 12 formed by an electroless Cu plating and a top surface thereof was not roughened. The arithmetic mean roughness of the top surface was 0.07 μm. The sample No. 2 had a layer corresponding to the seed layer 12 formed by an electroless Cu plating and a top surface thereof was roughened. The arithmetic mean roughness of the top surface was 0.31 μm. The sample No. 3 had a layer corresponding to the seed layer 12 formed by an electrolytic Cu foil and a top surface thereof was not roughened. The arithmetic mean roughness of the top surface was 0.09 μm. The sample No. 4 had a layer corresponding to the seed layer 12 formed by an electrolytic Cu foil and a top surface thereof was roughened. The arithmetic mean roughness of the top surface was 0.24 μm.

As the etching solution, CZ-8101 (manufactured by MEC Company Limited) was used. The pressure to spray the etching solution from a spray machine was 0.2 MPa. The process temperature was 30° C. and the process time was 30 seconds to 60 seconds. The arithmetic mean roughness Ra indicated in the Table 1 was measured using a laser microscope.

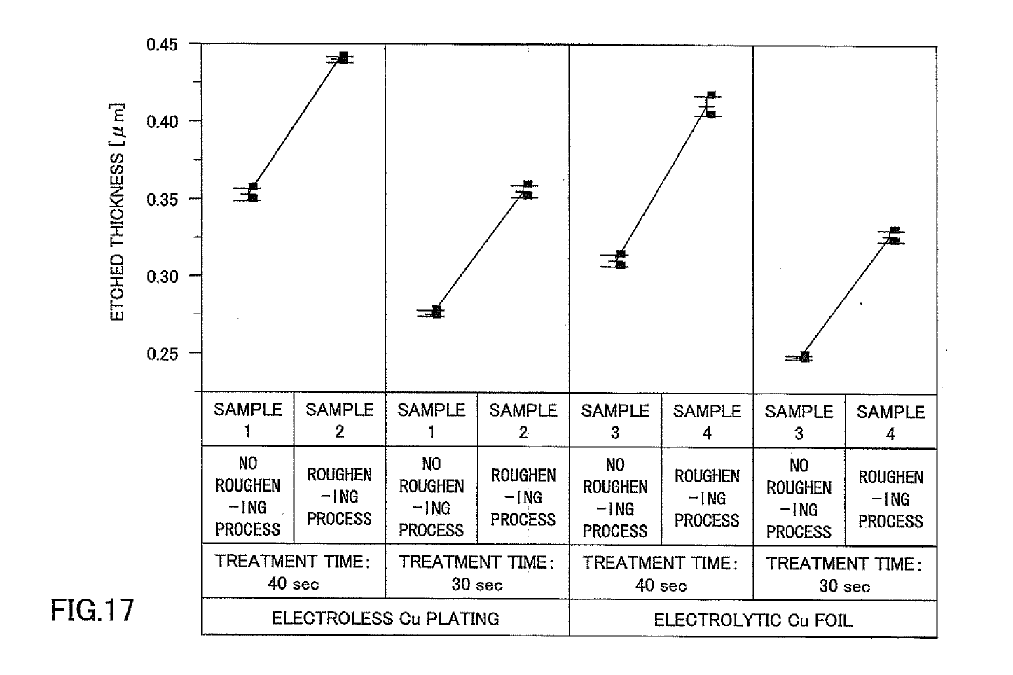

FIG. 17 illustrates etched film thickness of the samples No. 1 through No. 4. In FIG. 17, “treatment time” means an etching time. Etching was performed on the samples No. 1 through No. 4 with two kinds of treatment time, i.e., 40 sec and 30 sec. Comparing the sample No. 1 and the sample No. 2 in FIG. 17, it was appreciated that the etched film thickness of the sample No. 2 was larger than that of the sample No. 1 irrespective of the FE condition. Comparing the sample No. 3 and the sample No. 4 in FIG. 17, it was appreciated that the etched film thickness of the sample No. 4 was larger than that of the sample No. 3 irrespective of the FE condition. Thus, it was found that the etched film thickness of the sample, which was subjected to the roughening process, is larger than that of the sample, which was not subjected to the roughening process, in either of the sample of the electroless copper plating and the sample of the electrolytic copper foil. The etching rate of the sample, which was subjected to the roughening process, was 1.2 to 1.3 times higher than that of the sample, which was not subjected to the roughening process.

It was considered that the above-mentioned result was obtained because the surface area of copper was increased and the area reacting with the etching solution was increased. Therefore, it was assumed that an amount of etching per unit time of the roughened copper became larger than that of the copper which was not roughened, thereby reducing the etching time. Thus, it was confirmed that the etching time can be reduced and unnecessary etching can be suppressed by applying the roughening process to the seed layer.

All examples and conditional language recited herein are intended for pedagogical purposes to aid the reader in understanding the principles of the invention and the concepts contributed by the inventor to furthering the art, and are to be construed a being without limitation to such specifically recited examples and conditions, nor does the organization of such examples in the specification relates to a showing of the superiority and inferiority of the invention. Although the embodiments of the present invention(s) has(have) been described in detail, it should be understood that the various changes, substitutions, and alterations could be made hereto without departing from the spirit and scope of the invention.

What is claimed is:

1. A manufacturing method of a wiring board, comprising:
forming a seed layer on a top surface of an insulating layer so that a top surface of the seed layer has a predetermined roughness;
forming a resist film on the top surface of the seed layer, the resist film having an opening part through which a portion of the top surface of the seed layer corresponding to an area where a wire is formed is exposed;
forming the wire on the top surface of the seed layer by an electrolytic plating method using the seed layer as an electric supply layer;
removing the resist film after forming the wire; and
removing a portion of the seed layer on which the wire is not formed.

2. The manufacturing method according to claim 1, wherein forming the seed layer includes roughening the top surface of the seed layer.

3. The manufacturing method according to claim 2, wherein the predetermined roughness is defined by an arithmetic mean roughness Ra equal to or larger than 0.10 μm and equal to or smaller than 0.5 μm (0.10 μm≦Ra≦0.5 μm).

4. The manufacturing method according to claim 1, wherein forming the seed layer includes forming a metal layer by an electroless plating method so that the metal layer has a top surface having a predetermined roughness.

5. The manufacturing method according to claim 4, wherein the metal layer is made of a Cu—Ni—P alloy forming a surface having minute needle-like concavity and convexity.

6. The manufacturing method according to claim 5, wherein the predetermined roughness is defined by an arithmetic mean roughness Ra equal to or larger than 0.10 μm and equal to or smaller than 0.5 μm (0.10 μm≦Ra≦0.5 μm).
